(19) United States
(12) Patent Application Publication
(10) Pub. No.: US 2026/0020211 A1
(43) Pub. Date: Jan. 15, 2026

(54) MOUNTING DEVICE

(71) Applicant: TORAY ENGINEERING CO., LTD., Tokyo (JP)

(72) Inventors: Katsumi TERADA, Otsu-shi (JP); Satoru NARABA, Otsu-shi (JP)

(21) Appl. No.: 19/330,972

(22) Filed: Sep. 17, 2025

Related U.S. Application Data
(63) Continuation of application No. PCT/JP2024/010137, filed on Mar. 15, 2024.

(30) Foreign Application Priority Data
Mar. 28, 2023 (JP) 2023-050892

(51) Int. Cl. H05K 13/04; H05K 13/08

(52) U.S. Cl. CPC H05K 13/0408; H05K 13/0812

(57) ABSTRACT

A mounting device is provided that is configured to mount a chip component on a substrate. The mounting device includes a mounting head having an attachment tool that is configured to hold the chip component, and a head-side stage that is configured to adjust position and orientation of the attachment tool, a recognition unit configured to acquire an image from a direction perpendicular to a surface of the attachment tool, and a control unit operatively connected to the mounting head and the recognition unit. The control unit is configured to change a rotation angle of the head-side stage a plurality of times to acquire, by the recognition unit, images of a center identification mark provided at a portion movable together with the attachment tool, and configured to calculate a rotational center coordinate of the head-side stage from a plurality of pieces of position information of the center identification mark.

### CROSS-REFERENCE TO RELATED APPLICATIONS

This application is a continuation application of PCT International Application No. PCT/JP2024/010137 filed on Mar. 15, 2024, which claims priority to Japanese Patent Application No. 2023-050892 filed on Mar. 28, 2023 with Japan Patent Office. The entire disclosures of PCT International Application No. PCT/JP2024/010137 and Japanese Patent Application No. 2023-050892 are hereby incorporated herein by reference.

### BACKGROUND

### Field of the Invention

The present invention generally relates to a mounting device for mounting chip components on a substrate. More specifically, the present invention relates to a mounting device that aligns a chip component to a prescribed position on a substrate with high accuracy.

### Background Information

When a mounting device mounts a chip component such as a semiconductor chip on a substrate such as a wiring substrate, the mounting device performs mounting by aligning a chip component C to each mounting location SC of a substrate S having a plurality of mounting locations SC, as shown in FIG. 16. During alignment, substrate recognition marks AS (first substrate recognition mark AS1 and second substrate recognition mark AS2 arranged on a diagonal line) provided to each mounting location SC are used as a reference.

The reason for aligning a chip component C to a mounting location SC of the substrate S is to align the positions of the electrodes of the chip component C to the electrodes of the substrate S, thereby ensuring reliable electrical connection. Thus, the chip recognition marks used for aligning the chip component C are provided on the electrode surface such that the positions of the electrodes can be recognized with high accuracy.

Therefore, in face-up mounting in which the electrodes of the substrate S and the electrodes of the chip component C face in the same direction, the substrate recognition marks AS and the chip recognition marks AC (first chip recognition mark AC1 and second chip recognition mark AC2) face in the same direction, as shown in FIG. 17A. In addition, in face-down mounting in which the electrodes of the substrate S and the electrodes of the chip component C face each other, the substrate recognition marks AS and the chip recognition marks AC (first chip recognition mark AC1 and second chip recognition mark AC2) face each other, as shown in FIG. 17B.

Although the method of recognizing the substrate recognition marks AS and the chip recognition marks AC are different for face-up mounting and face-down mounting (for example, see Japanese Laid Open Patent Application Publication No. 2017-208522 (Patent Document 1) for face-up mounting and Japanese Laid Open Patent Application Publication No. 2018-190958 (Patent Document 2) for face-down mounting), the alignment operation after recognition of the positional relationships is the same for both. That is, a chip component C provided with a first chip recognition mark AC1 and a second chip recognition mark AC2 is aligned with respect to a substrate S provided with a first substrate recognition mark AS1 and a second substrate recognition mark AS2, as shown in FIG. 18A. That is, the relative position of the first chip recognition mark AC1 with respect to the first substrate recognition mark AS1, and the relative position of the second chip recognition mark AC2 with respect to the second substrate recognition mark AS2, are aligned to arrange the chip component C at the mounting location SC, as shown in FIG. 18B.

### SUMMARY

An example of the specific alignment method will be described with reference to FIGS. 19A, 19B and 19C. First, FIG. 19A shows a state in which an attachment tool 42 is holding a chip component C in FIGS. 17A and 17B. Although the recognition methods are different between the face-up mounting shown in FIG. 17A and the face-down mounting shown in FIG. 17B, the first substrate recognition mark AS1, the second substrate recognition mark AS2, the first chip recognition mark AC1, and the second chip recognition mark AC2 are recognized to obtain information on each position. The rotation angle θ of the chip component C with respect to the substrate S, and the horizontal (X and Y direction) positional deviation of the chip component center CC with respect to the mounting location center SCC of the mounting location SC are determined from the position information of each recognition mark that has been obtained.

In principle, if the chip component C is rotated about the chip component center CC to correct for the angle θ and then the positional deviation of the chip component center CC with respect to the mounting location center SCC is corrected, the alignment will be completed. However, the rotational axis of the attachment tool 42 does not necessarily coincide with the chip component center CC. Therefore, as shown in FIG. 19B, first, the position of the rotational center through which the rotational axis of the attachment tool 42 passes is predicted and defined as virtual center VC, and, under the assumption that the chip component C will be corrected by the angle θ about the virtual center VC, correction in the horizontal direction (ΔX in the X direction and ΔY in the Y direction) after the rotation angle correction is calculated. Then, as shown in FIG. 19C, by correcting the ΔX and ΔY, the chip component C is aligned to the prescribed mounting location SC.

The virtual center VC in FIGS. 19A, 19B and 19C is the reference for the center coordinates of the rotational axis in the correction in the rotation direction, and is estimated by calculating from the trajectory obtained through image processing of the chip recognition marks AC, etc., captured by a recognition means, when the attachment tool 42 is rotated by a rotation angle of approximately 10°. However, calculation of the position of this virtual center VC involves various error factors, making it difficult for the virtual center VC to coincide with the actual rotational center. The effect of the virtual center not coinciding with the rotational center will be described with reference to FIGS. 20A, 20B and 20C.

FIG. 20A shows a state in which the attachment tool 42 is holding a chip component C. The first substrate recognition mark AS1, the second substrate recognition mark AS2, the first chip recognition mark AC1, and the second chip recognition mark AC2 are recognized to obtain information on each position. Then, under the assumption that the chip component C will be corrected by angle θ about the virtual center VC of the attachment tool 42 serving as the rotational center, correction in the horizontal direction (ΔX in the X direction and ΔY in the Y direction) after the rotation angle correction is calculated. However, at this stage, the position of the virtual center VC contains, with respect to the rotational center RC, errors of dx1 in the X direction and of dy1 in the Y direction (FIG. 20B).

Therefore, at the stage of FIG. 20B, the chip component C has been subjected to correction of rotation angle θ about the rotational center RC, and the horizontal direction correction carried out in FIG. 20C is calculated on the assumption of rotating about the virtual center VC (which contains errors of ΔX in the X direction and of ΔY in the Y direction with respect to the rotational center RC). Therefore, ultimately, errors of dx2 in the X direction and of dy2 in the Y direction occur, as shown in FIG. 20C.

For example, if the error of the virtual center VC with respect to the rotational center RC is about 0.1 mm, an error of about several μm could occur when the correction of the rotation angle θ is about 1°. While an error of several μm is allowable in mounting when the electrode pitch exceeds 100 μm, such an error is not allowable in this day and age when mounting accuracy of less than 1 μm is required. In order to achieve highly-accurate alignment, it is necessary to bring the virtual center VC even closer to the rotational center RC.

One object is to provide a mounting device that accurately ascertains the coordinates of the rotational center during positional adjustment, enabling highly-accurate alignment when mounting a chip component such as a semiconductor chip on a substrate such as a wiring substrate.

In view of the state of the known technology, a mounting device according to a first aspect is configured to mount a chip component on a substrate. The mounting device comprises a mounting head having an attachment tool that is configured to hold the chip component, and a head-side stage that is configured to adjust position and orientation of the attachment tool, an elevating unit configured to raise and lower the mounting head in a direction perpendicular to the substrate, a substrate stage configured to hold the substrate, a recognition unit configured to acquire an image from a direction perpendicular to a surface of the attachment tool, and a control unit operatively connected to the mounting head, the elevating unit, the substrate stage, and the recognition unit. The control unit is configured to change a rotation angle of the head-side stage a plurality of times to acquire, by the recognition unit, images of a center identification mark provided at a portion movable together with the attachment tool, and configured to calculate a rotational center coordinate of the head-side stage from a plurality of pieces of position information of the center identification mark.

According to a second aspect, with the mounting device mentioned above, the center identification mark is provided on the attachment tool.

According to a third aspect, with any one of the mounting devices mentioned above, the mounting device further comprises a tool holding unit configured to hold the attachment tool while the attachment tool is detached from the mounting head.

According to a fourth aspect, with any one of the mounting devices mentioned above, the control unit is configured to calculate a relative position between the center identification mark and the rotational center coordinate, configured to align the rotational center coordinate to the center identification mark by the head-side stage while the attachment tool is detached from the mounting head, and configured to reattach the attachment tool to the mounting head.

According to a fifth aspect, with any one of the mounting devices mentioned above, the center identification mark is provided on a dummy chip that is held by the attachment tool.

According to a sixth aspect, with any one of the mounting devices mentioned above, a line indicating an X direction and/or a Y direction is provided on the attachment tool.

According to a seventh aspect, with any one of the mounting devices mentioned above, the center identification mark is provided at a center of the surface of the attachment tool.

According to the present disclosure, highly-accurate alignment is possible when mounting a chip component such as a semiconductor chip on a substrate such as a wiring substrate.

### BRIEF DESCRIPTION OF THE DRAWINGS

FIG. 1 is a schematic diagram of a mounting device according to a first embodiment of the present disclosure.

FIG. 2 is a block diagram showing a control system according to the first embodiment of the present disclosure.

FIG. 3 is a diagram showing an attachment tool according to the first embodiment of the present disclosure.

FIGS. 4A, 4B, 4C, and 4D are diagrams explaining a process by which a center identification mark provided on an attachment tool is aligned to rotational center coordinates in a mounting device according to the first embodiment of the present disclosure, with FIG. 4A showing a state in which the relative position of the rotational center coordinates with respect to the center identification mark is being acquired, FIG. 4B showing a state in which the attachment tool is lowered and brought into contact with a tool holding means, FIG. 4C showing a state in which a mounting head with the attachment tool detached is raised, and FIG. 4D showing a state in which the center coordinates of a head-side stage are aligned to the center identification mark.

FIGS. 5A, 5B and 5C are diagrams explaining a process by which a center identification mark provided on an attachment tool is aligned to rotational center coordinates in the mounting device according to the first embodiment of the present disclosure, with FIG. 5A showing a state in which the mounting head holds the attachment tool with the center identification mark aligned to the rotational center, FIG. 5B showing a state in which the tool holding means has released the attachment tool, and FIG. 5C showing a state in which the center of the field of view of a recognition means is aligned to the rotational center.

FIGS. 6A, 6B, 6C and 6D are diagrams explaining the principle of aligning a center identification mark provided on an attachment tool to rotational center coordinates in the mounting device according to the first embodiment of the present disclosure, with FIG. 6A showing a state in which the rotational center is calculated from changes in the position of the center identification mark when the rotation angle is changed by the head-side stage, FIG. 6B showing a state in which the center identification mark is brought close to the calculated rotational center, after which the rotational center is recalculated from changes in the position of the center identification mark when the rotation angle is changed by the head-side stage, FIG. 6C showing a state in which the center of gravity of the center identification mark is used to calculate the rotational center coordinates, and FIG. 6D showing a state in which the calculation accuracy of the rotational center coordinates satisfies a condition.

FIGS. 7A and 7B are diagrams explaining angular correction of the attachment tool used in the first embodiment of the present disclosure, with FIG. 7A showing an attachment tool on which lines indicating the X and Y directions are inscribed, and FIG. 7B showing a state in which the attachment tool is tilted.

FIG. 8 is a diagram explaining a dummy chip used in a second embodiment of the present disclosure.

FIGS. 9A and 9B are diagrams explaining a center identification mark of the dummy chip according to the second embodiment of the present disclosure, with FIG. 9A showing a state when the rotational center is determined, and FIG. 9B showing a state in which the center identification mark is aligned to the rotational center.

FIGS. 10A, 10B, 10C and 10D are diagrams explaining a process by which a center identification mark provided on a dummy chip is aligned to rotational center coordinates in a mounting device according to the second embodiment of the present disclosure, with FIG. 10A showing a state in which the relative position of the rotational center coordinates with respect to the center identification mark is being acquired, FIG. 10B showing a state in which the dummy chip is lowered and brought into contact with a chip holding means, FIG. 10C showing a state in which a mounting head with the dummy chip detached is raised, and FIG. 10D showing a state in which the rotational center coordinates of a head-side stage are aligned to the center identification mark.

FIGS. 11A, 11B, 11C and 11D are diagrams explaining a process by which a center identification mark provided on a dummy chip is aligned to rotational center coordinates in the mounting device according to the second embodiment of the present disclosure, with FIG. 11A showing a state in which the mounting head holds the dummy chip with the center identification mark aligned to the rotational center, FIG. 11B showing a state in which the chip holding means has released the dummy chip, FIG. 11C showing a state in which the center of the field of view of a recognition means is aligned to the rotational center, and FIG. 11D showing a state in which the attachment tool has removed the dummy chip.

FIG. 12 is a schematic diagram of a mounting device that is a modified example of an embodiment of the present disclosure.

FIGS. 13A and 13B are diagrams explaining a process by which a center identification mark is aligned to rotational center coordinates in a mounting device that is a modified example of an embodiment of the present disclosure, with FIG. 13A showing a state in which the relative position of the rotational center coordinates with respect to the center identification mark is being acquired, and FIG. 13B showing a state in which the position of the center identification mark is adjusted and aligned to the rotational center coordinates.

FIG. 14 is a diagram showing an example in which the present disclosure is applied to a device configuration different from those of the embodiments.

FIG. 15 is a diagram showing a second example in which the present disclosure is applied to a device configuration different from those of the embodiments.

FIG. 16 is a diagram explaining a substrate on which a plurality of chip components are mounted, mounting locations in which the chip components are mounted, and each substrate recognition mark.

FIGS. 17A and 17B are diagrams, with FIG. 17A showing a state in which chip recognition marks and substrate recognition marks are facing the same direction, and FIG. 17B showing a state in which the chip recognition marks and the substrate recognition marks face each other, when mounting a chip component on a substrate.

FIGS. 18A and 18B are diagrams explaining mounting locations and substrate recognition marks, with FIG. 18A showing the arrangement of the substrate recognition marks, and FIG. 18B showing a state in which a chip component has been placed in a mounting location.

FIGS. 19A, 19B and 19C are diagrams explaining the process by which a chip component is aligned to a mounting location on a substrate, with FIG. 19A showing the position of the chip component before alignment, FIG. 19B showing a state in which rotation angle adjustment has been carried out, and FIG. 19C showing a state after alignment has been carried out.

FIGS. 20A, 20B and 20C are diagrams explaining the process by which a chip component is aligned to a mounting location on a substrate in a state in which the position of a virtual center of an attachment tool includes an error with respect to the rotational center, with FIG. 20A showing the position of the chip component before alignment, FIG. 20B showing a state in which rotation angle adjustment has been carried out, and FIG. 20C showing a state after alignment has been carried out.

### DETAILED DESCRIPTION OF EMBODIMENTS

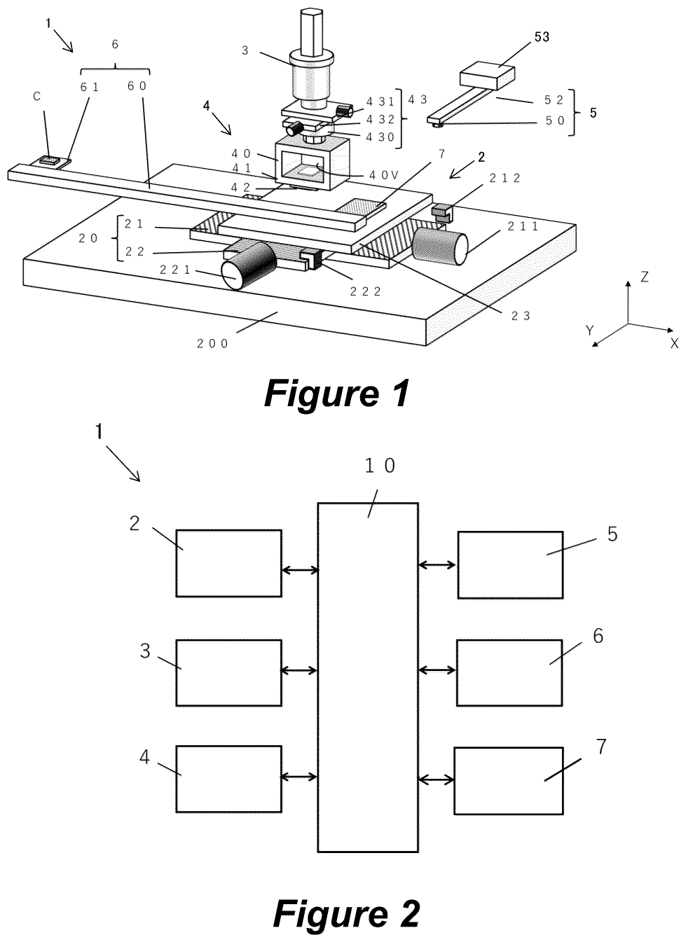

Selected embodiments of the present disclosure will be described below with reference to the drawings. FIG. 1 is a schematic diagram of a mounting device 1 according to a first embodiment of the present disclosure. In addition, FIG. 2 is a block diagram showing a control system of the mounting device 1.

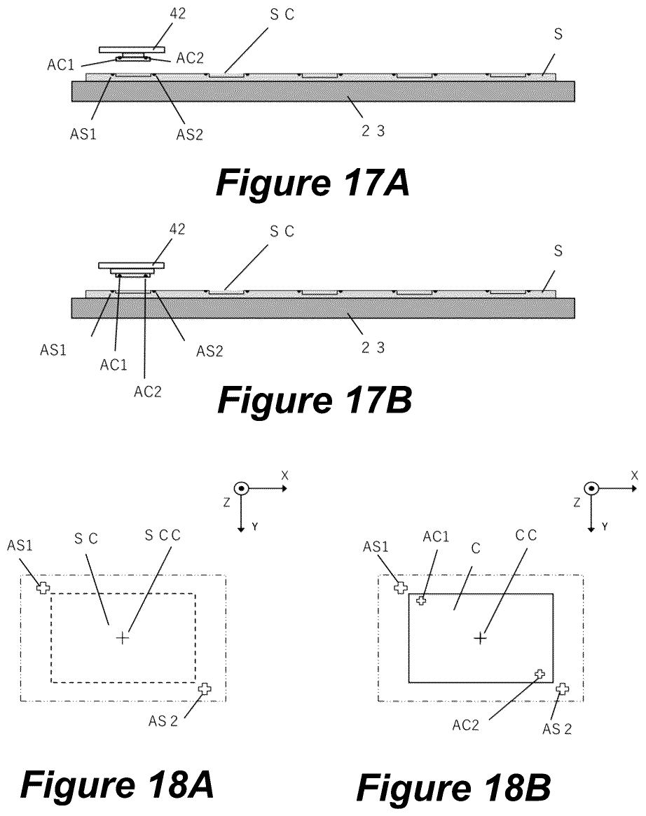

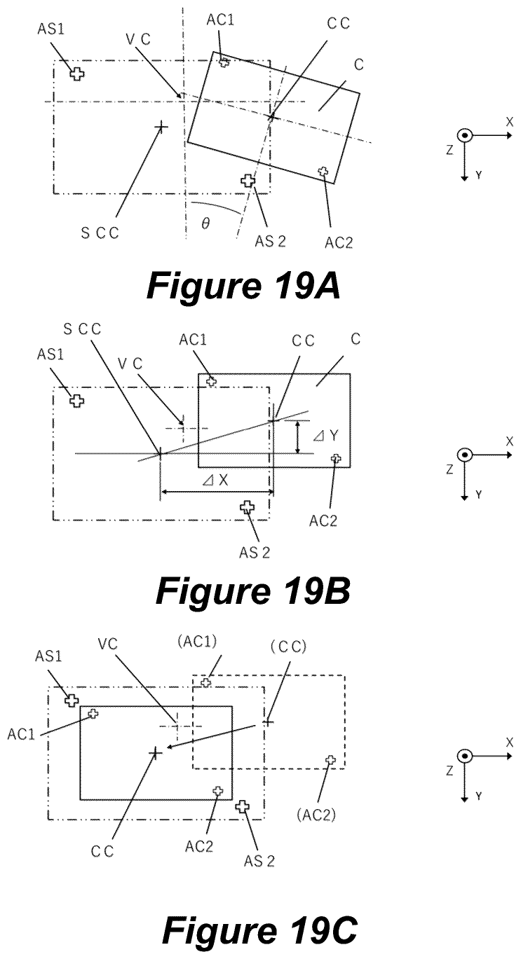

The mounting device 1 is a device that mounts a chip component C on a substrate S, as seen in FIGS. 16 and 17A (17B), and is configured to recognize substrate recognition marks AS (AS1 and AS2) of the substrate S and chip recognition marks AC (AC1 and AC2) of the chip component C to perform alignment.

The constituent elements of the mounting device 1 include a substrate stage 2, an elevating means or head 3, a mounting head 4, a recognition means or unit 5, a chip conveyance means or unit 6 (e.g., a chip conveyor), a tool holding means or unit 7 (e.g., a tool holder), and a control unit or electronic controller 10.

In the mounting device 1 shown in FIG. 1, the substrate stage 2 includes a stage movement control means or unit 20 and a suction table 23. The suction table 23 uses suction to hold the substrate S placed on the surface thereof, and the suction table 23 can be moved by the stage movement control means 20 in an X-direction and a Y-direction, which form the in-plane direction of the substrate surface, while holding the substrate S.

The stage movement control means 20 includes a Y-direction stage movement control means or unit 22 and an X-direction stage movement control means or unit 21. The Y-direction stage movement control means 22 is configured to move the suction table 23 linearly in the Y direction. The X-direction stage movement control means 21 is provided on a base 200 and is configured to move the Y-direction stage movement control means 22 linearly in the X direction. The Y-direction movement control means 22 has a Y-direction servo 221 and a movable part that is disposed on a slide rail and on which the suction table 23 is mounted, and the movement and position of the movable part are controlled by the Y-direction servo 221. In the illustrated embodiment, the movement can also be prevented by operating a Y-direction clamp 222. The X-direction movement control means 21 has an X-direction servo 211 and a movable part that is disposed on a slide rail and on which the Y-direction movement control means 22 is mounted, and the movement and position of the movable part are controlled by the X-direction servo 211. In the illustrated embodiment, the movement can also be prevented by operating an X-direction clamp 212. The X-direction servo 211 and the Y-direction servo 221 are servo motors.

The elevating means 3 is fixed to a gate-shaped frame (not shown) and has a vertical drive shaft provided perpendicular to the suction table 23, and the mounting head 4 is connected to the vertical drive shaft. The elevating means 3 has a function of driving the mounting head 4 up and down, and of applying pressure in accordance with a setting. Furthermore, the elevating means 3 preferably has a function of rotating the mounting head 4 about the vertical drive shaft. In the illustrated embodiment, the elevating means 3 includes at least one electronic actuator or motor (i.e., an elevation actuator or motor) that drives the vertical drive shaft to drive the mounting head 4 up and down and rotate the mounting head 4 about the vertical drive shaft.

In the mounting device 1, the elevating means 3 is supported from two directions (by the gate-shaped frame), and is linked linearly to the mounting head 4, so lateral force is less likely to be applied to the mounting head 4 during pressure application; therefore, there is no lateral misalignment during mounting, enabling highly-accurate mounting.

The mounting head 4 holds and pressure-bonds the chip component C parallel to the substrate S (which is held by the suction table 23 of the substrate stage 2). The constituent elements of the mounting head 4 include a head body 40, a heater unit or heater 41, an attachment tool 42, and a head-side stage 43. The head body 40 is linked to the elevating means 3 via the head-side stage 43, and the heater unit 41 is disposed and fixed on the lower side thereof. The heater unit 41 has a heat generating function, and heats the chip component C through the attachment tool 42. In addition, the heater unit 41 has a function of using suction to hold the attachment tool 42, using a reduced-pressure flow channel. The attachment tool 42 uses suction to hold the chip component C, and is replaced to match the shape of the chip component C. The head-side stage 43 is configured to adjust the position and the orientation of the attachment tool 42. In particular, the head-side stage 43 is configured to adjust the attachment tool 42 in the X direction and the Y direction (within the plane that suctions the chip component C) (i.e., the position of the attachment tool 42), and in the rotation angle θ direction (i.e., the angular orientation of the attachment tool 42 (rotation about an axis in the Z-direction)). In the illustrated embodiment, with the mounting device 1 of the present embodiment, the position of the attachment tool 42 is adjusted through the heater unit 41 and the head body directly connected to the head-side stage 43. In the illustrated embodiment, the head-side stage 43 includes one or more electronic actuators or motors, for example.

The head-side stage 43 includes the electronic actuators that form a 0 angle adjustment means or unit 430, an X-direction adjustment means or unit 431, and a Y-direction adjustment means or unit 432, respectively. In the configuration of the mounting device 1, the 0 angle adjustment means 430 is closest to the attachment tool 42, and thus, the rotational center of the 0 angle adjustment means 430 can be moved within the XY plane by the X-direction adjustment means 431 and the Y-direction adjustment means 432. In addition, in a state in which the mounting head 4 is holding the attachment tool 42, the rotational center of the 0 angle adjustment means 430 (in the XY coordinate system) becomes the rotational center of the attachment tool 42.

The mounting device 1 of the first embodiment is configured so that it is possible to observe the substrate surface through the mounting head 4 by forming the attachment tool 42 from a transparent member, by providing a through-hole, or the like. The heater unit 41 is also made of a transparent member or is provided with an opening. In addition, the mounting head 4 has a space in which an image capture unit 50 of the recognition means 5 can move. That is, the head body 40 has a structure composed of side plates linked above the heater unit 41 and a top plate linking the two side plates.

The recognition means 5 focuses on and photographs a target object through the mounting head 4 (through the attachment tool 42 and the heater unit 41) from a direction perpendicular to the surface on which the attachment tool 42 holds the chip component C. In the first embodiment, the constituent elements of the recognition means 5 include the image capture unit 50, an optical path 52, and an imaging means or unit 53 linked to the optical path 52. Thus, in the illustrated embodiment, the recognition means 5 includes a recognition mechanism. In the illustrated embodiment, the imaging means 53 includes an electronic image sensor, such as a charge-coupled device (CCD), an active-pixel sensor (CMOS sensor), and the like, for example.

The image capture unit 50 is disposed (above) facing a recognition target of which the imaging means 53 acquires an image, and brings the recognition target within the field of view. In the illustrated embodiment, the image capture unit 50 forms an objective, and includes an optical element, such as a lens or mirror, or combinations of several optical elements, for example. In the illustrated embodiment, the recognition means 5 can also include a reflecting means or unit formed by a mirror or prism, for example.

Additionally, the recognition means 5 is configured to be capable of being moved, by a drive mechanism (not shown), such as an electronic actuator or motor, in the in-plane direction of the substrate S (and the chip component C) within the head space. Furthermore, the recognition means 5 preferably also has a function of moving in a direction perpendicular to the substrate S (Z direction) so that the focal position can be adjusted.

The mounting head 4 is moved perpendicular to the substrate S by the elevating means 3, and this operation can be performed independently of the operation of the recognition means 5. Therefore, the head space 40V is designed to have dimensions such that the recognition means 5 entering the head space 40V will not interfere even if the mounting head 4 moves in the vertical direction.

The movable range of the image capture unit 50 of the recognition means 5 is not limited to within the head space 40V. It is also possible to move outside of the head space 40V and over the substrate S to acquire position information of the substrate recognition marks AS, and the like.

In addition, if it is configured such that position information can be acquired within the movable range of the image capture unit 50, it is possible to calculate the position information of each point within the captured image.

The chip conveyance means 6 includes a conveyor that is formed by a conveyance rail 60 and a chip slider 61, and is configured so that the chip slider 61 holds and slides the chip component C supplied from a chip supply unit (not shown) to directly below the attachment tool 42.

Here, the chip supply unit (not shown) places the chip component C at a set position on the chip slider 61. If necessary, the position where the chip component C is placed on the chip slider 61 may be recognized by a recognition mechanism (not shown). In addition, the chip conveyance means 6 may include a position adjustment means or unit that adjusts the in-plane direction (XY direction) position of the chip component C placed on the chip slider 61. In this case, the position adjustment means includes an adjuster or an electronic actuator that adjusts the in-plane direction position of the chip component C. Thus, controlling the positions of the chip slider 61 and the chip component C placed on the chip slider 61 allows the chip component C to be transferred to within a prescribed range of the attachment tool 42. After the attachment tool 42 has held the chip component C, the chip slider 61, which has released the chip component C, moves to a retracted position.

In the case of face-down mounting, the bonding surface of the chip component C is turned downward by a chip inversion means or unit (not shown) and handed off onto the chip slider 61 and then to a prescribed position on the attachment tool 42, but the chip component C that has been inverted by the chip inversion means may be directly handed off to the attachment tool 42.

In a state of being placed directly below the mounting head 4, the tool holding means 7 includes a holder that receives the attachment tool 42 from the mounting head 4 side and holds the attachment tool 42 so that there is no positional deviation in the X, Y, and 0 directions. In particular, the holder of the tool holding means 7 is formed by a vacuum chuck or vacuum suction mechanism, and the operation of holding and releasing the attachment tool 42 is carried out by turning vacuum suction of the vacuum chuck or vacuum suction mechanism on and off. However, the configuration of the holder of the tool holding means 7 is not limited to this, and can include different holding/releasing mechanism. The tool holding means 7 is on standby at a retracted position away from directly below the mounting head 4, and is placed directly below the mounting head 4 when holding the attachment tool 42. In FIG. 1, the tool holding means 7 is configured to move along the conveyance rail 60, but no limitation is imposed thereby, and may be configured to be moved by other driving means, or the like.

As shown in the block diagram of FIG. 2, the control unit 10 is operatively connected to the substrate stage 2, the elevating means 3, the mounting head 4, the recognition means 5, the conveyance means 6, and the tool holding means 7.

Essentially, the main constituent elements of the control unit 10 include at least one processor having a CPU (Central Processing Unit) and a storage device or computer memory, and an interface for communicating with each device is included as necessary. In addition, the control unit 10 can have a built-in program to perform calculations using acquired data and to output according to the calculation result. Furthermore, it is desirable for the control unit 10 to have the function of recording and using the acquired data and calculation result as data for new calculations.

The control unit 10 is connected to the substrate stage 2 and controls the operations of the X-direction stage movement control means 21 and the Y-direction stage movement control means 22, thereby controlling the in-plane movement of the suction table 23. In addition, the control unit 10 controls the suction table 23 to control the application and release of suction to and from the substrate S.

The control unit 10 is connected to the elevating means 3, and has the function of controlling the position of the mounting head 4 in the up and down direction (Z direction) as well as controlling the pressure applied when the chip component C is pressure-bonded to the substrate S.

The control unit 10 is connected to the mounting head 4, and has the function of controlling the application and release of suction to and from the chip component C by the attachment tool 42 and the heating temperature of the heater unit 41. In addition, the control unit 10 has the function of connecting to the head-side stage 43 of the mounting head 4 and controlling the XY position and the rotation angle θ of the attachment tool 42 (as well as the head body 40 and the heater unit 41).

The control unit 10 is connected to the recognition means 5 and has the function of controlling the position of the image capture unit 50 in the horizontal (in the XY plane) direction and the vertical direction (Z direction), as well as controlling the imaging means 53 to acquire image data. Furthermore, the control unit 10 has an image processing function, and has a function of calculating position information of each point in the image of the imaging means. In addition, the control unit 10 has the function of calculating the rotational center coordinates, serving as a reference for calculating the correction in the rotation direction from the trajectory of a point that has moved due to the rotation.

The control unit 10 is connected to the chip conveyance means 6, and has the function of controlling the position of the chip slider 61 that moves along the conveyance rail 60.

Then control unit 10 is connected to the tool holding means 7, and has the function of controlling the holding and release of the attachment tool 42.

The process by which the rotational center coordinates of the head-side stage 43 are determined in the mounting device 1 will be described below.

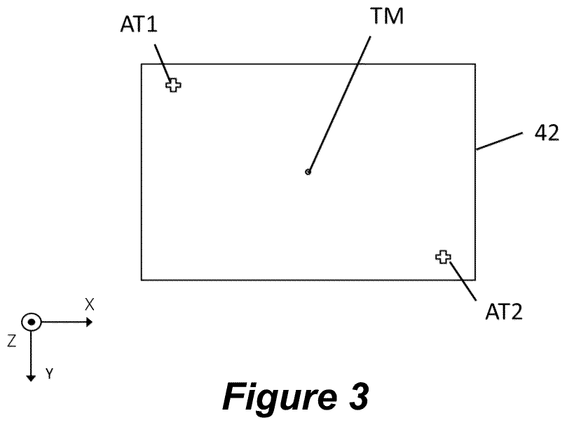

FIG. 3 describes the attachment tool 42 used in the first embodiment of the present invention. The attachment tool 42 of FIG. 3 is characterized in that a center identification mark TM is provided near the center. Here, “near the center” means that it is preferably the center but may be away from the center by several millimeters. In the illustrated embodiment, as seen in FIG. 3, tool recognition marks AT (AT1 and AT2) are provided on a surface of the attachment tool 2 at positions corresponding to the chip recognition marks AC (AC1 and AC2) of the chip component C (FIGS. 17A (17B) and 18B) to acquire relative position between the attachment tool 42 and the chip component C.

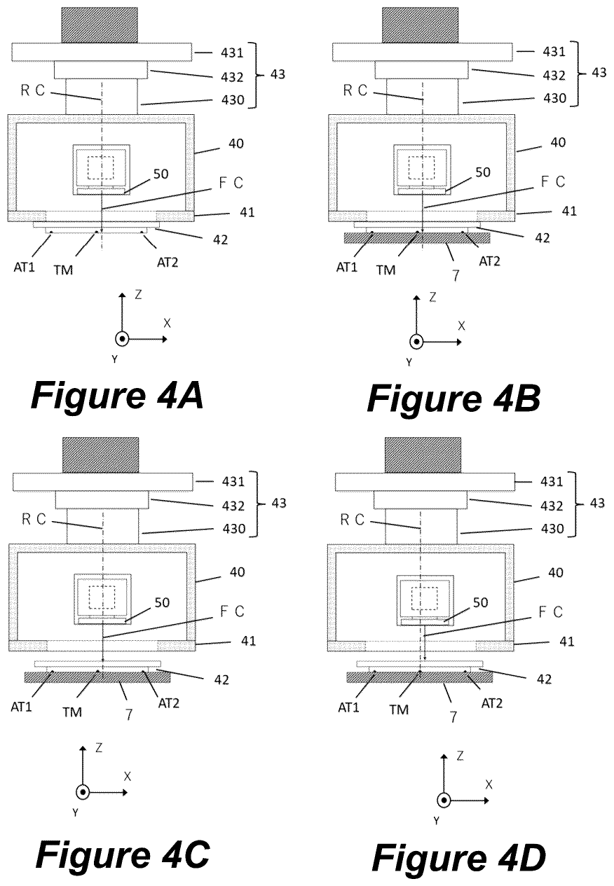

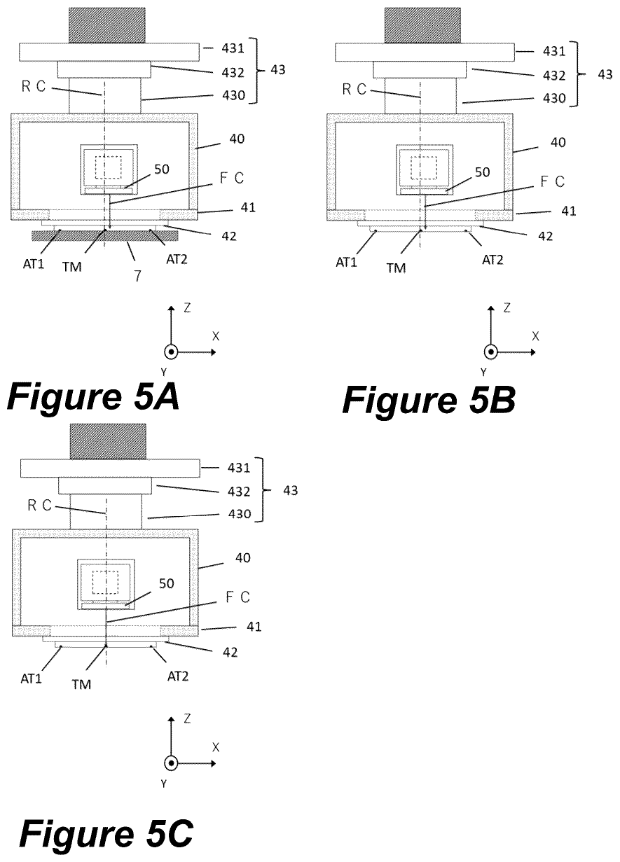

FIGS. 4A, 4B, 4C, 4D, 5A, 5B and 5C show the process by which the rotational center of the attachment tool 42 is determined when the head-side stage 43 carries out θ angle adjustment and, further, the process by which the center identification mark TM is aligned to the coordinates of the rotational center.

FIG. 4A is a state in which the (heater unit 41 of the) mounting head 4 is holding the attachment tool 42 shown in FIG. 3. Here, the rotational center coordinates of the attachment tool 42 (in the XY plane) coincides with the coordinates of the rotational center RC of the θ angle adjustment means 430.

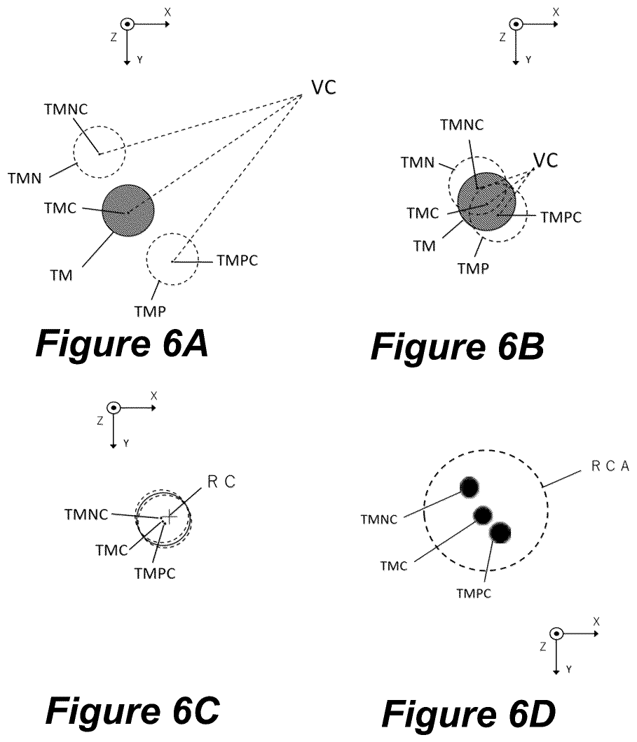

In the state shown in FIG. 4A, the center identification mark TM does not coincide with the rotational center RC. Therefore, when the rotation angle of the attachment tool 42 is changed by the θ angle adjustment means 430, the position of the center identification mark TM changes, an example of which is shown in FIG. 6A. FIG. 6A shows, relative to the original center identification mark TM, the position of the center identification mark TM when the θ angle is changed in the positive direction (indicated as TMP) and the position of the center identification mark TM when the θ angle is changed in the negative direction (indicated as TMN). It is possible to calculate the virtual center VC through computation from the arc shape formed by the coordinate positions of TMC, TMPC, and TMNC, which are the positions of the center (positions of the center of gravity) of the center identification mark. Here, the amount of change in the θ angle is preferably about plus or minus 10 degrees, preferably within the range of 5 to 15 degrees. If the angle is too small, the positional change of the center identification mark TM becomes small, and if the angle is too large, the field of view required for observation becomes wider, resulting in a corresponding decrease in image resolution, which is not preferable.

The coordinates of the drive mechanism of the recognition means 5 at which the rotational center RC and the center of the field of view FC of the recognition means 5 thus obtained coincide, are determined as the coordinates of the virtual center VC and stored in the control unit 10. The virtual center VC is used as the position of the rotational center RC serving as a reference for calculating the correction in the rotation direction.

In FIG. 4A, the positional relationship between the center identification mark TM and the virtual center VC can be calculated, and FIG. 4B to FIG. 5B show the process of moving the center identification mark TM to the position of the virtual center VC.

FIG. 4B shows a state in which the tool holding means 7 is placed below the attachment tool 42, after which the mounting head 4 is lowered and the attachment tool 42 is brought into close contact with the tool holding means 7. In this state, the tool holding means 7 holds the attachment tool 42 by suction, or the like. Thereafter, the (heater unit 41 of the) mounting head 4 releases the attachment tool 42 and rises (FIG. 4C).

Thereafter, in order to make the relative position between the virtual center VC and the (center TMC of the) center identification mark TM zero, the X-direction adjustment means 431 and the Y-direction adjustment means 432 of the head-side stage 43 are driven to adjust the positions of the head body 40 and the heater unit 41, thereby aligning the center identification mark TM to the virtual center VC (FIG. 4D). Then, the mounting head 4 is lowered, as shown in FIG. 5A and the heater unit 41 is brought into close contact with the attachment tool 42 and suctioned, after which the tool holding means 7 releases the attachment tool 42 and the mounting head 4 is raised to the state shown in FIG. 5B.

Incidentally, if the virtual center VC determined in the state shown in FIG. 4A coincides with the rotational center RC and the positional adjustment is carried out thereafter with high accuracy, the position of the center identification mark TM will coincide with the rotational center RC. However, the virtual center VC and the rotational center RC often do not coincide; therefore, it is desirable to repeat the operation of FIG. 4A onward from the state shown in FIG. 5B. That is, after the center identification mark TM is aligned to the virtual center VC determined in the state shown in FIG. 6A, when the rotation angle of the attachment tool 42 is changed by the θ angle adjustment means 430, if the position of the center identification mark TM changes as shown in FIG. 6B, a new virtual center VC is determined from this state. Thereafter, the same process is repeated, and when the positional change of the center identification mark TM becomes small (FIG. 6C) and the positional change of the center point TMC of the center identification mark TM falls within an allowable range RCA as shown in FIG. 6D, it may be determined that the virtual center VC coincides with the rotational center RC.

Thereafter, as shown in FIG. 5C, the center identification mark TM may be observed and the position of the image capture unit 50 may be adjusted such that the rotational center RC is placed in the center of the image set in the image acquired by the recognition means 5.

The rotational center adjustment step need not be executed before each mounting; if changes due to the effects of temperature, etc., are small, it is sufficient to execute the rotational center adjustment step only once during the initial adjustment. In practice, it is preferable to execute the rotational center adjustment step after each time a certain number of the chip components C have been mounted, after a certain amount of temperature change in the vicinity of the recognition means, after a certain amount of change in the positional deviation after mounting, and after each time the substrate S is replaced.

The center identification mark TM is preferably attached to the attachment tool 42 but may be attached to a location other than the attachment tool 42 as long as it is possible to make adjustments to match the virtual center VC and the rotational center RC in conjunction with the attachment tool 42.

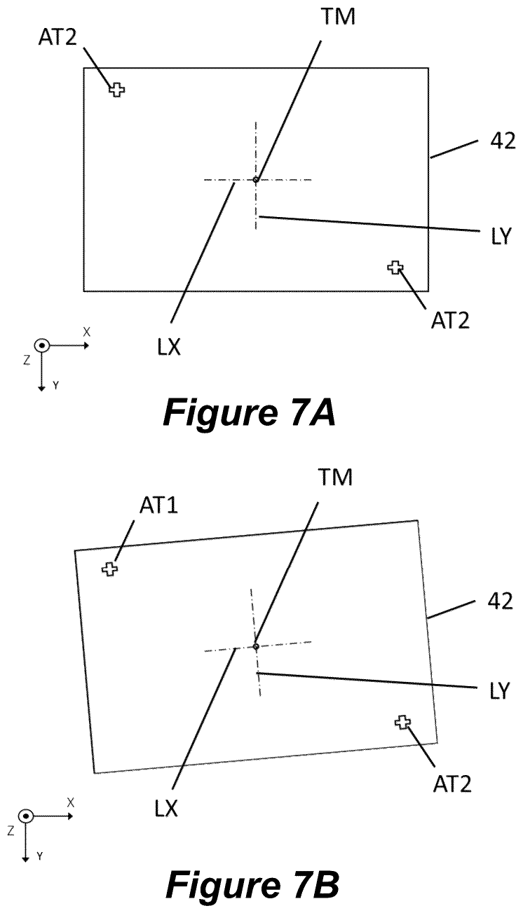

In addition to the center identification mark TM shown in FIG. 3, a line LX or LY in the X direction and/or the Y direction may be provided on the attachment tool 42, as shown in FIG. 7A. In the illustrated embodiment, as shown in FIG. 7A, a line LX in the X direction and a line LY in the Y direction are both inscribed on the attachment tool 42. As a result, in addition to aligning the center identification mark TM to the rotational center RC, it is possible to correct the tilt of the attachment tool 42 held by the heater unit 41 in a state of being tilted with respect to the XY coordinate system, as shown in FIG. 7B. When also correcting tilt, the 0 angle adjustment means 430 is driven, in addition to the X-direction adjustment means 431 and the Y-direction adjustment means 432, between FIGS. 4C and 4D.

In the foregoing first embodiment, the center identification mark TM provided on the attachment tool 42 is used to determine the rotational center RC of the head-side stage 43. A second embodiment will be described as a method of determining the position of the rotational center RC by another means.

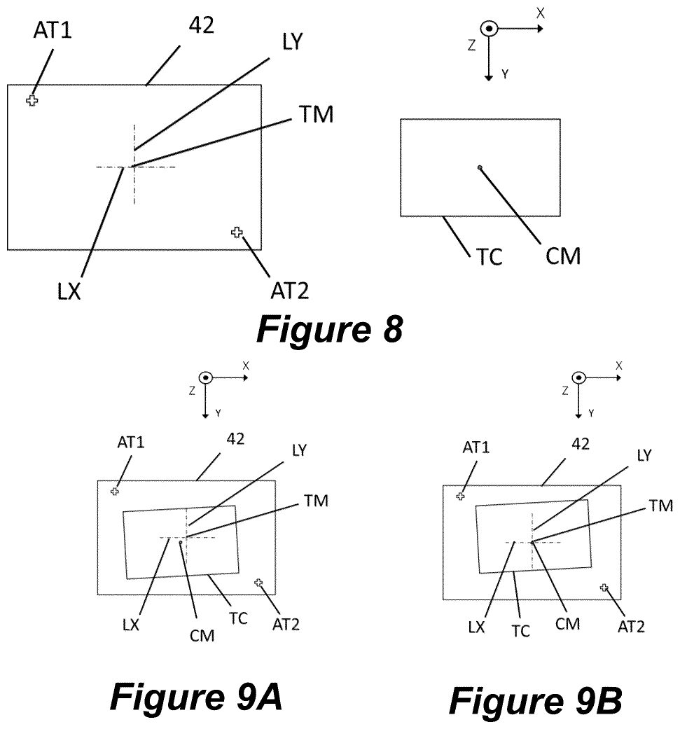

In the second embodiment, a dummy chip TC provided with a center identification mark CM, such as that shown in FIG. 8, is used. FIG. 8 shows an example in which the center identification mark TM is provided on the attachment tool 42, but when using the dummy chip TC, the center identification mark TM is not necessary. However, the center identification mark TM may be used as a reference for checking the position of the rotational center RC in the attachment tool 42, determined using the dummy chip TC.

FIG. 9A shows a state in which the attachment tool 42 is holding the dummy chip TC provided with the center identification mark CM, and FIG. 9B shows a state in which the dummy chip TC is moved and the center identification mark CM is aligned to the rotational center RC. FIGS. 9A and 9B show an example in which the center identification mark TM of the attachment tool 42 coincides with the rotational center RC. In FIG. 9A, if the dummy chip TC is being held by the attachment tool 42, the center identification mark CM of the dummy chip TC moves in conjunction with the attachment tool 42.

In the second embodiment, the tool holding means 7 may be used as a chip holding means or unit in the configuration of the mounting device 1, but if the chip slider 61 of the chip conveyance means 6 is used as a chip holding means, the tool holding means 7 shown in FIG. 1 is not necessary. An example in which the chip slider 61 is used is illustrated in the following description.

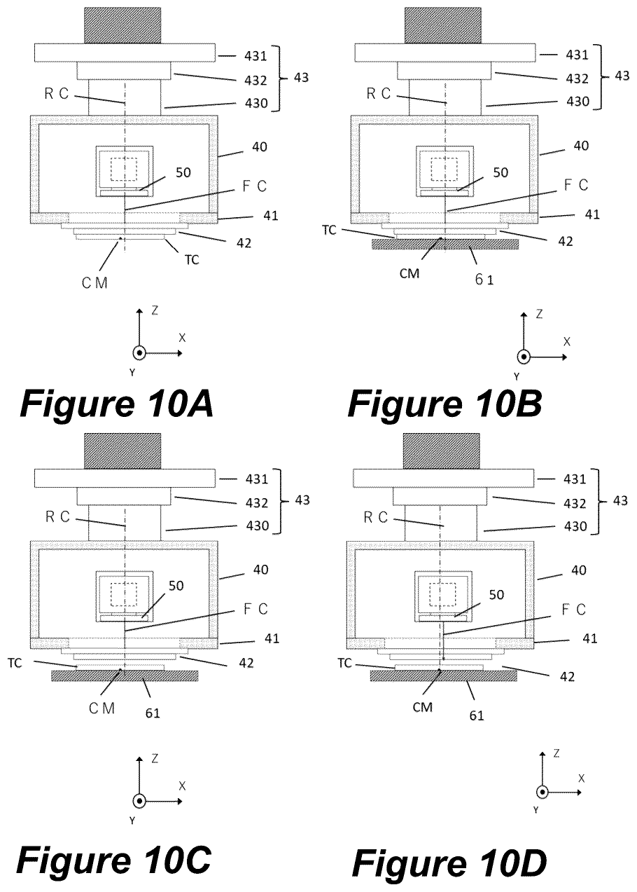

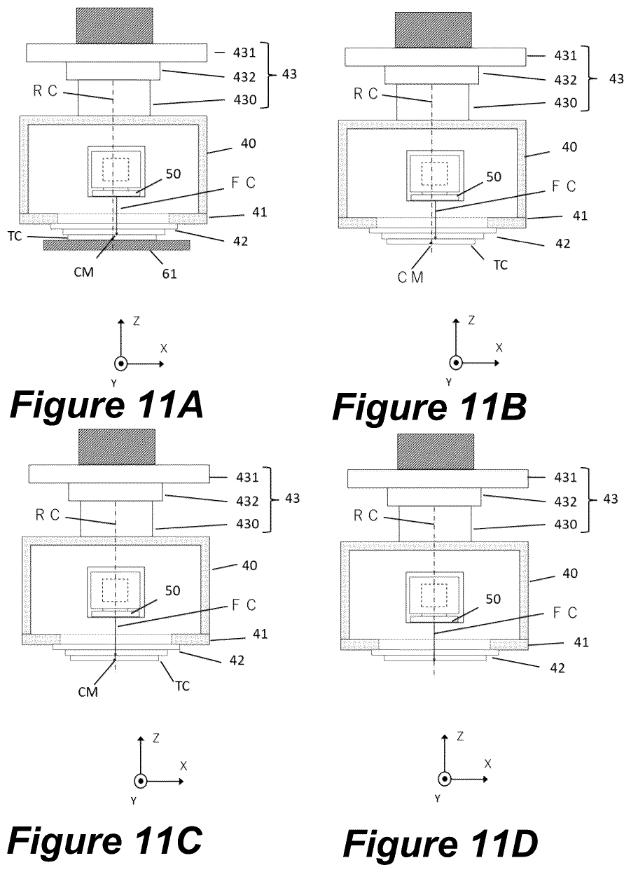

FIGS. 10A, 10B, 10C, 10D, 11A, 11B, 11C and 11D show the process by which the rotational center RC is determined when the head-side stage 43 carries out θ angle adjustment and, further, the process by which the center identification mark CM of the dummy chip TC is aligned to the coordinates of the rotational center RC.

FIG. 10A shows a state in which the attachment tool 42 is holding the dummy chip TC shown in FIG. 8. Here, the rotational center coordinates of the attachment tool 42 (in the XY plane) coincides with the coordinates of the rotational center RC of the θ angle adjustment means 430.

In the state shown in FIG. 10A, the center identification mark CM of the dummy chip TC does not coincide with the rotational center RC. Therefore, by changing the rotation angle of the attachment tool 42 with the θ angle adjustment means 430, it is possible to calculate the virtual center VC by computation. Here, the amount of change in the θ angle is preferably about plus or minus 10 degrees, preferably within the range of 5 to 15 degrees, similarly to when using the center identification mark TM.

In FIG. 10A, the positional relationship between the center identification mark CM and the virtual center VC has been determined, and FIG. 10B to FIG. 11B show the process of moving the center identification mark CM to the position of the virtual center VC.

FIG. 10B shows a state in which the chip slider 61 is placed below the dummy chip TC, after which the mounting head 4 is lowered, and the dummy chip TC is brought into close contact with the chip slider 61. In this state, the chip slider 61 holds the dummy chip TC by suction, or the like. Thereafter, as shown in FIG. 10C, the attachment tool 42 releases the dummy chip TC and rises.

Thereafter, in order to make the relative position between the virtual center VC and the (center CMC of the) center identification mark CM zero, the X-direction adjustment means 431 and the Y-direction adjustment means 432 of the head-side stage 43 are driven to adjust the positions of the head body 40, the heater unit 41, and the attachment tool 42, thereby aligning the center identification mark CM to the virtual center VC (FIG. 10D). Then, the mounting head 4 is lowered, as shown in FIG. 11A, and the attachment tool 42 is brought into close contact with the dummy chip TC and suctioned, after which the chip slider 61 releases the dummy chip TC and the mounting head 4 is raised to the state shown in FIG. 11B.

Incidentally, if the virtual center VC determined in the state shown in FIG. 10A coincides with the rotational center RC and the positional adjustment is carried out thereafter with high accuracy, the position of the center identification mark CM will coincide with the rotational center RC. However, the virtual center VC and the rotational center RC often do not coincide; therefore, it is desirable to repeat the operation of FIG. 10A onward from the state shown in FIG. 11B. This is the same as the method using the center identification mark TM, described with reference to FIGS. 6A, 6B, 6C and 6D.

Thereafter, as shown in FIG. 11C, the center identification mark CM may be observed and the position of the image capture unit 50 may be adjusted such that the rotational center RC is placed in the center of the image FC set in the image acquired by the recognition means 5, after which the dummy chip TC is released. When being released, the dummy chip TC is preferably handed off to the chip slider 61.

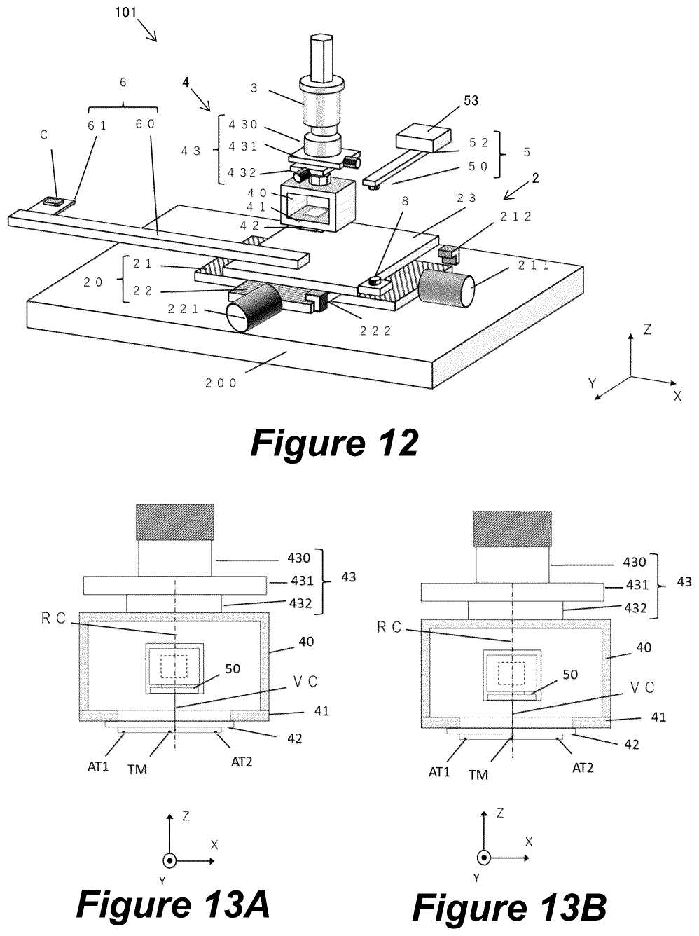

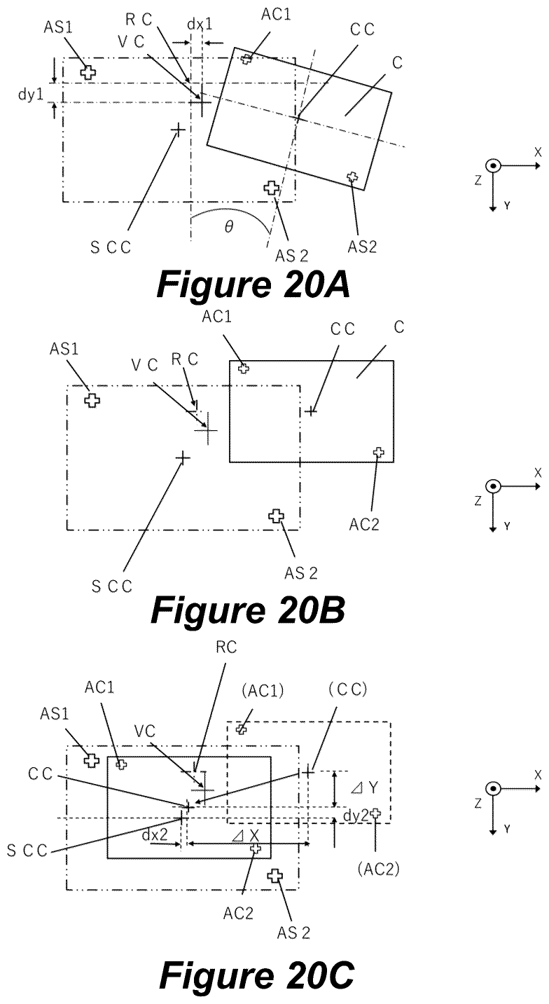

In the foregoing description, the θ angle adjustment means 430 is closest to the attachment tool 42; thus, in order to move the attachment tool 42 relative to the θ angle adjustment means 430, it is necessary to temporarily remove the attachment tool 42 from the mounting head 4. In contrast, in a mounting device 101 shown in FIG. 12, which is a modified example of the embodiments of the present invention, the X-direction adjustment means 431 and the Y-direction adjustment means 432 are present between the θ angle adjustment means 430 and the attachment tool 42. Therefore, it is possible to use the X-direction adjustment means 431 and the Y-direction adjustment means 432 to align the center identification mark TM to the rotational center RC without requiring removal from the mounting head 4. FIGS. 13A and 13B show the state described above. As shown in FIG. 13A, in a state in which the center identification mark TM is away from the rotational center RC, the process of increasing the accuracy of the virtual center VC as shown in FIGS. 6A, 6B, 6C and 6D can be executed without removing the attachment tool 42, and it is possible to align the center identification mark TM to the rotational center RC, as shown in FIG. 13B. However, in the configuration of the mounting device 101 of FIG. 12, when carrying out angle adjustment as shown in FIGS. 20A to 20B, the entire XY coordinate system defined by the X-direction adjustment means 431 and the Y-direction adjustment means 432 is tilted, making it difficult to calculate the correction amounts in the X and Y directions.

As described above, according to the present disclosure, it is possible to obtain, with high accuracy, the coordinates of the rotational center of the attachment tool that holds the chip component, when adjusting the rotation angle of the chip component. Therefore, it is possible to suppress errors in positional correction when mounting a chip component on a substrate, thereby making it possible to achieve highly-accurate mounting.

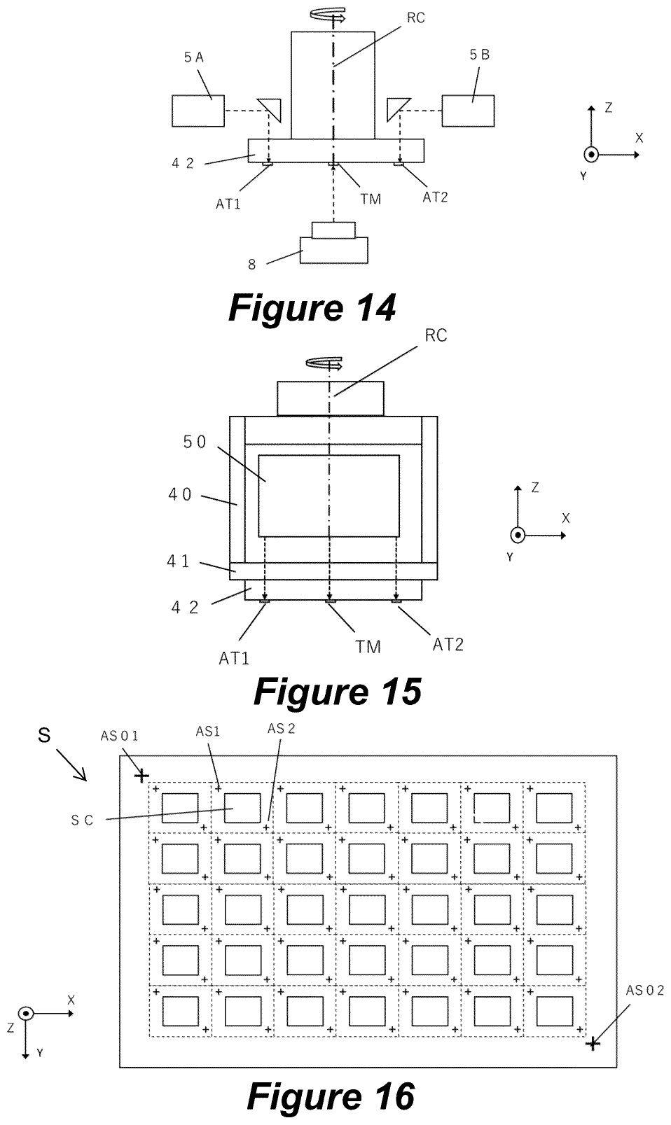

The present invention can be used in ways other than the embodiments described above. For example, as shown in FIG. 14, a recognition means or unit 8 that is basically identical to the recognition means 5, except for observing the center identification mark TM from below may be used. In FIG. 14, a configuration is shown in which the tool recognition marks AT (AT1 and AT2) are recognized by a pair of recognition means or units 5A and 5B, each of which is basically identical to the recognition means 5, except for observing the tool recognition marks AT on a lower surface of the attachment tool 42 through the attachment tool 42. When using the high-resolution recognition means 5 in the manner shown in FIG. 15, the coordinates of the rotational center can be determined and set within the image capture field of view, without moving the image capture unit 50. This enables highly accurate adjustment that does not include errors during movement of the recognition means.

What is claimed is:

1. A mounting device configured to mount a chip component on a substrate, the mounting device comprising:
a mounting head having an attachment tool that is configured to hold the chip component, and a head-side stage that is configured to adjust position and orientation of the attachment tool;
an elevating unit configured to raise and lower the mounting head in a direction perpendicular to the substrate;
a substrate stage configured to hold the substrate;
a recognition unit configured to acquire an image from a direction perpendicular to a surface of the attachment tool; and
a control unit operatively connected to the mounting head, the elevating unit, the substrate stage, and the recognition unit,
the control unit being configured to change a rotation angle of the head-side stage a plurality of times to acquire, by the recognition unit, images of a center identification mark provided at a portion movable together with the attachment tool, and configured to calculate a rotational center coordinate of the head-side stage from a plurality of pieces of position information of the center identification mark.

2. The mounting device according to claim 1, wherein
the center identification mark is provided on the attachment tool.

3. The mounting device according to claim 2, further comprising
a tool holding unit configured to hold the attachment tool while the attachment tool is detached from the mounting head.

4. The mounting device according to claim 3, wherein
the control unit is configured to calculate a relative position between the center identification mark and the rotational center coordinate, configured to align the rotational center coordinate to the center identification mark by the head-side stage while the attachment tool is being detached from the mounting head, and configured to reattach the attachment tool to the mounting head.

5. The mounting device according to claim 1, wherein
the center identification mark is provided on a dummy chip that is held by the attachment tool.

6. The mounting device according to claim 1, wherein
a line indicating an X direction and/or a Y direction is provided on the attachment tool.

7. The mounting device according to claim 2, wherein
the center identification mark is provided at a center of the surface of the attachment tool.

8. The mounting device according to claim 2, wherein
a line indicating an X direction and/or a Y direction is provided on the attachment tool.

9. The mounting device according to claim 3, wherein
a line indicating an X direction and/or a Y direction is provided on the attachment tool.

10. The mounting device according to claim 4, wherein
a line indicating an X direction and/or a Y direction is provided on the attachment tool.

11. The mounting device according to claim 5, wherein
a line indicating an X direction and/or a Y direction is provided on the attachment tool.

12. The mounting device according to claim 3, wherein
the center identification mark is provided at a center of the surface of the attachment tool.

13. The mounting device according to claim 4, wherein
the center identification mark is provided at a center of the surface of the attachment tool.
